(19) United States
(12) Patent Application Publication
(10) Pub. No.: US 2007/0051623 A1
(43) Pub. Date: Mar. 8, 2007

(54) Method of making sputtering target and target

(75) Inventors: Tyrus W. Hansen, New Era, MI (US); Michael G. Launsbach, Yorktown, VA (US)

Correspondence Address: Mr. Edward J. Timmer, P.O. Box 770, Richland, MI, 49083-0770, US

(73) Assignee: Howmet Corporation

(21) Appl. No.: 11/513,822

(22) Filed: Aug. 31, 2006

Related U.S. Application Data
(60) Provisional application No. 60/714,670, filed on Sep. 7, 2005.

(51) Int. Cl. C23C 14/00

(52) U.S. Cl. 204/298.12

(57) ABSTRACT

Method of making a sputtering target wherein the number of processing steps is reduced by providing melted sputtering target material in a heated mold and solidifying the melted material in the mold using a unidirectional heat removal process to produce a sputtering target with a selective grain orientation. The method can produce a solidified sputtering target having a selectively oriented multigrain microstructure or a selectively oriented single crystal microstructure suited or tailored to the sputtering process to be subsequently employed using the target.

This application claims priority and benefits of provisional application Ser. No. 60/714,670 filed Sep. 7, 2005.

### FIELD OF THE INVENTION

The present invention relates to a method of making a sputtering target as well as to the sputtering target produced having controlled selective grain orientation.

### BACKGROUND OF THE INVENTION

A current method of making a metal alloy cylindrical sputtering target involves standard vacuum induction melting (VIM) and casting of a rectangular slab or ingot and then rolling to shape. The process also may involve hot isostatic pressing prior to the rolling operation. The metal or alloy ingot is rolled and heated several times to align the grains of the ingot microstructure and thereby increase the pass through flux (PTF) of the sputtering target that is eventually rolled to cylindrical shape. The cylindrical sputtering target then is machined out of the rolled ingot. This process requires lengthy lead times and has poor material utilization, also resulting in a very thin cross section once the PTF is acceptable.

### SUMMARY OF THE INVENTION

The present invention provides in an embodiment a method of making a sputtering target wherein the number of processing steps is reduced by providing melted sputtering target material in a heated mold and solidifying the melted material in the mold using a unidirectional heat removal process to produce a sputtering target having a controlled preferential crystal or grain orientation.

The method can produce a solidified sputtering target pursuant to another embodiment of the invention having a controlled selectively oriented single or multiple crystal or grain microstructure oriented to suit a particular sputtering process to be subsequently employed using the target to improve the target pass through flux.

In illustrative embodiments of the invention, the mold can comprise a ceramic investment shell mold or a permanent metallic mold having a mold cavity in the net or near-net shape of the sputtering target such that the solidified sputtering target requires little, if any, machining to final shape. The mold is preheated prior to introducing melted target material therein.

The invention is advantageous to provide a sputtering target which can be cast to final or near-final size requiring only minimal machining prior to use.

The invention is advantageous to provide grain orientation control of the target, reduced manufacturing lead times from material selection to target manufacture, and increased material selection flexibility such as alloying options

Other advantages, features, and embodiments of the present invention will become apparent from the following description.

### DESCRIPTION OF THE DRAWINGS

FIG. 1 is a schematic view of a ceramic investment shell mold having a helical (pigtail) crystal selector for use in practicing an embodiment of the invention to make a multicrystalline or a single crystal, disc-shaped sputtering target having a preferential grain orientation.

FIG. 2 is a schematic view of a ceramic investment shell mold for use in practicing an embodiment of the invention to make a columnar grain, rectangular cross-section sputtering target having preferential grain orientation.

FIGS. 3, 4 and 5 are schematic perspective views of single crystal sputtering targets pursuant to other illustrative embodiments of the invention having different controlled grain orientations.

### DESCRIPTION OF THE INVENTION

The present invention provides a method of making a sputtering target by providing melted sputtering target material in a heated mold and solidifying the melted material in the mold using a unidirectional heat removal process. The target material can comprise a metal or an alloy of two or more metals that is to be subsequently sputtered onto a substrate. For purposes of illustration and not limitation, the invention envisions making sputtering targets that can include, but are not limited to, high temperature melting transition metals or alloys such as cobalt alloys, nickel alloys, and iron alloys; refractory metals or alloys such as chromium alloys and tantalum alloys; and other high temperature melting metals and alloys which melt above about 2000 degrees F. For purposes of further illustration and not limitation, a sputtering target material can comprise a cobalt alloy including one or more alloying elements selected from the group consisting of boron, chromium, platinum, tantalum, ruthenium, rhenium, niobium, copper, vanadium, silicon, silver, gold, iron, aluminum, zirconium, and nickel. For example, the target can comprise cobalt base alloys including, but not limited to, a Co—Ta—Zr alloy, Co—Nb—Zr, Co—Ta—B alloy, Co—Cr—Pt—B alloy, Co—Cr—Pt—B—Cu alloy used commercially as sputter targets in manufacture of flat screen displays, data storage components, and electronic components.

A sputtering target material also can comprise an iron alloy including one or more alloying elements selected from the group consisting of boron, chromium, platinum, tantalum, ruthenium, rhenium, niobium, copper, vanadium, silicon, silver, gold, aluminum, zirconium and cobalt. For example, the target can comprise iron base alloys including, but not limited to, a Fe—Co—Ta—Zr and Fe—Co—Cr—B alloy commercially used as sputter targets in manufacture of data storage components and electronic components.

A sputtering target material also can comprise a nickel alloy including one or more alloying elements selected from the group consisting of boron, chromium, platinum, tantalum, ruthenium, rhenium, niobium, copper, vanadium, silicon, silver, gold, iron, aluminum, and cobalt. For example, the target can comprise nickel base alloys including, but not limited to, a Ni—Cr alloy and Ni—V alloy commercially used as sputter targets in manufacture of data storage components and electronic components.

Still another sputtering target material also can comprise a chromium base alloy including one or more alloying elements selected from the group consisting of boron, cobalt, platinum, tantalum, ruthenium, rhenium, niobium, copper, vanadium, silicon, silver, gold, iron, aluminum, and nickel. For example, the target can comprise chromium base alloys including, but not limited to, a Cr—V alloy and Cr—Si alloy commercially used as sputter targets in manufacture of flat screen displays, data storage components, and electronic components.

A further sputtering target material also can comprise a tantalum base alloy including one or more alloying elements selected from the group consisting of boron, cobalt, platinum, iron, ruthenium, rhenium, niobium, copper, vanadium, silicon, silver, gold, chromium, aluminum, and nickel. For example, the target can comprise chromium base alloys including, but not limited to, a Ta—Co—B alloy and Ta—Al alloy commercially used as sputter targets in manufacture of data storage components and electronic components.

Such sputtering target metals and alloys can be obtained commercially from raw materials suppliers with appropriate purity of particular sputtering target applications, or they can be made by melting appropriate amounts of the alloying elements and master alloys thereof. The target metals or alloys supplied commercially typically are in the form of briquets, powder, chunks, etc.

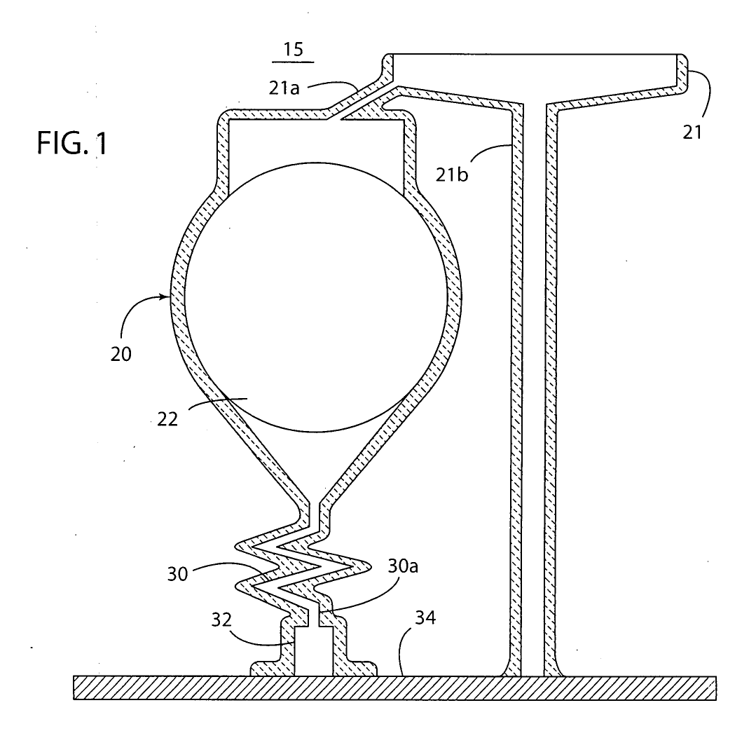

In practice of an illustrative embodiment of the invention shown in FIG. 1, a metallic sputtering target material is melted in a crucible (not shown) in a heated casting furnace chamber 15 and poured into a preheated ceramic investment shell mold 20 disposed in the furnace. Although only one shell mold 20 is shown in FIG. 1, multiple shell molds 20 typically are connected to a common pour cup 21 by respective runners 21a to form a cluster shell mold assembly. Pour cup 21 is disposed on support post 21b. Each shell mold 20 has a disc-shaped mold cavity 22, which has the net or near net shape of the desired sputtering target. The disc-shaped mold cavity 22 is oriented so that its major flat sides are vertically oriented. Each mold cavity 22 is connected to a crystal selector passage 30 (commonly known as a helix or pig-tail passage) that is communicated at its open lower end 30a to a crystal nucleation chamber 32. The nucleation chamber 32 communicates at its open lower end to a water cooled chill plate 34 so that multiple crystals or grains nucleate in the molten material in the chamber 32 and grow upwardly in the chamber 32. The crystal selector passage 30 functions to select one crystal or grain growing upwardly in chamber 32 having a desired crystal orientation for the sputtering target for propagation through the molten material in the associated mold cavity therebove.

The cluster mold assembly is made by the well known lost wax process wherein a wax pattern of the cluster mold assembly is repeatedly dipped in ceramic slurry, drained of excess slurry, stuccoed with coarse ceramic stucco particulates, and dried to build up a shell mold on the pattern assembly. The pattern assembly then is selectively removed by thermal treatment such as melting out of the pattern, or other means, leaving the ceramic shell mold assembly. The ceramic shell mold assembly is fired at elevated temperature in preparation for casting.

To effect directional solidification, the melted sputtering target material is poured into the pour cup 21 of the shell mold assembly and flows via runners 21a into each mold 20 filling its mold cavity 22, passage 30, and chamber 32 where the molten material in the mold cavity is subjected to unidirectional heat removal using chill plate 34 and withdrawing the cluster mold assembly gradually from the open bottom of the casting furnace at a controlled rate in known manner to propagate a single crystal or grain with desired grain orientation selected by passage 30 through the melted material in the mold cavity 22.

In lieu of the crystal selector passage 30, a single crystal seed (not shown) having a desired preferred crystal orientation can be located at the bottom of each mold cavity 20 to nucleate a single crystal having the orientation of the seed for propagation upwardly through the mold cavity thereabove as the cluster mold assembly on the chill plate is withdrawn gradually from the open end of the casting furnace. Directional solidification processes of this general type for making single crystal turbine blade castings are described in U.S. Pat. Nos. 3,700,023; 3,763,926; and 4,190,094, the teachings of which are incorporated herein by reference.

Unidirectional heat removal can be effected by the well known mold withdrawal technique wherein the melt-filled mold 20 on chill plate 34 is withdrawn from the casting furnace 15 at a controlled rate as described. Alternately, a power down technique can be employed wherein induction coils of the casting furnace disposed about the melt-filled mold on the chill plate are de-energized in controlled sequence. Regardless of the DS casting technique employed, generally unidirectional heat removal is established in the melted material in the mold cavities to propagate one or more crystals or grains through the melted material in the mold cavity 22.

The crystal selector 30 (or the single crystal seed) in the mold 20 is selected such that the single crystal propagated through the melted target material in the mold 20 has the desired grain or crystal orientation. For example, the crystal selector 30 can be configured to permit only a single grain or crystal of desired orientation to propagate into the melted target material. Alternately, the single crystal seed if used is provided with a grain orientation from which the melted material epitaxially solidifies and propagates upwardly through the mold. The crystal selector passage or single crystal seed thereby controls the grain orientation of the solidified sputtering target in the mold.

The invention is not limited to solidifying the melted target material in an investment shell mold since it also can be practiced using other molds such as a permanent metallic mold having one or more mold cavities in the near-net shape of the sputtering target. Such molds can be configured to produce single crystal or columnar grain solidified targets by providing a suitable chill in the mold or selectively cooling a particular region of the mold.

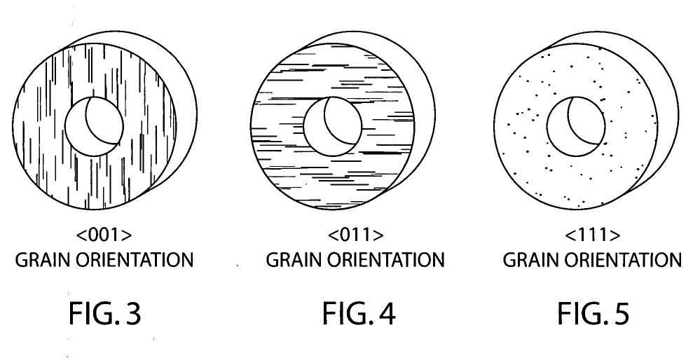

The shape of the sputtering target produced in the mold 20 is determined by the shape of the mold cavity 22. In the above-described exemplary embodiment, the mold cavity shape replicates the disc shape of the sputtering target. However, the mold cavity 22 can have any shape suited for the intended sputtering application such as disc-shape, rectangular plate shape, square plate shape, cylindrical billet shape which can be cut transversely to yield target discs, or any other shape. For example, FIGS. 3, 4 and 5 are schematic perspective views of single crystal sputtering targets 100 having an annular-disc shape pursuant to other illustrative embodiments of the invention using suitably shaped annular mold cavities. These sputtering targets can have a controlled preferential <001> grain orientation, <011> grain orientation, or <111> grain orientation, respectively, aligned in a particular direction of the sputtering target to enhance the pass through flux of the sputtering target for a particular subsequent sputtering process to be employed. The grain orientation used will depend in part on the particular metal or alloy used to make the sputtering target. For example, for a sputtering target made of a cobalt base alloy, the <001> grain orientation typically is aligned parallel with the major flat surface of the sputtering target from which surface material is to be sputtered. The grain orientation of the sputtering target is selected and controlled to enhance the pass through flux of the sputtering target for a particular sputtering process to be later employed.

The invention is not limited to making single crystal sputtering targets and can be practiced to make multicrystalline sputtering targets such as columnar grain sputtering targets wherein a plurality of grains propagate through the melted material in the mold to form a microstructure having a plurality of elongated grains extending generally along an axis of the target in the direction of unidirectional heat removal.

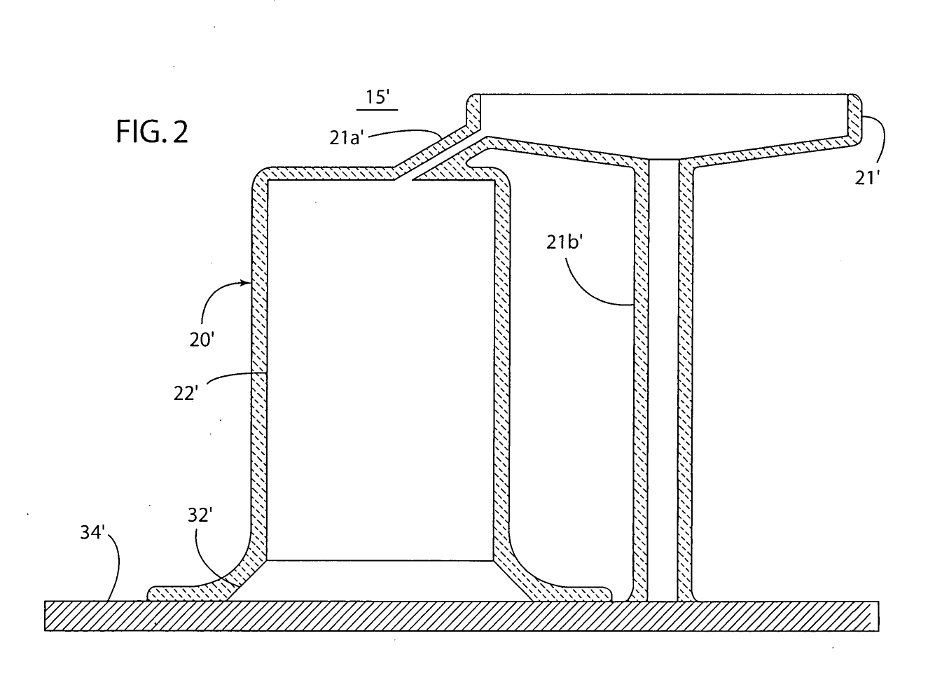

In practice of another illustrative embodiment of the invention shown in FIG. 2, a metallic sputtering target material is melted in a crucible (not shown) in a casting furnace chamber 15′ and poured into a preheated ceramic investment shell mold 20′ disposed in the casting furnace. Although only one shell mold 20′ is shown in FIG. 2, multiple shell molds 20′ are connected to a common pour cup 21′ by respective runners 21a′ to form a cluster shell mold assembly. Each shell mold has a rectangular cross-section-shaped mold cavity 22′, which has the net or near net shape of the desired sputtering target. The mold cavity 22′ is oriented so that its major flat sides are vertically oriented as shown. Each mold cavity 22′ is communicated at its lower end to a crystal nucleation chamber 32′. The nucleation chamber 32′ communicates at its open lower end to a water cooled chill plate 34′ so that multiple crystals having a desired grain orientation nucleate in the molten material and grow upwardly in the chamber 34′ and then through the mold cavity 20′ to form a columnar grain target microstructure.

To effect directional solidification, the melted sputtering target material is poured into the pour cup 21′ and flows via runners 21a′ into each mold 20′ filling its mold cavity 22′ and chamber 32′ where the molten material in the mold cavity is subjected to unidirectional heat removal using chill plate 34′ and withdrawing the cluster shell mold assembly gradually from the open bottom of the casting furnace at a controlled rate in known manner to propagate the multiple crystals or grains with desired grain orientation from chamber 32′ upwardly through the melted material in the mold cavity 22′.

Unidirectional heat removal can be effected by the well known mold withdrawal technique wherein the melt-filled mold 20′ on chill plate 34′ is withdrawn from the casting furnace 15′ at a controlled rate as described. Alternately, a power down technique can be employed wherein induction coils disposed about the melt-filled mold on the chill plate are de-energized in controlled sequence. Regardless of the DS casting technique employed, generally unidirectional heat removal is established in the melted material in the mold cavities to propagate multiple crystals or grains through the melted material.

The invention also envisions solidifying the melted material in a mold using a unidirectional heat removal process as described above to make a sputtering target having selective grain orientation and then cutting or otherwise machining slices or sections from the target with the slices or sections being used as a sputtering target in a subsequent sputtering process.

The following EXAMPLES are offered to further illustrate but not limit the invention.

### EXAMPLE 1

Multicrystalline sputtering targets were made by providing a melted Co—Ta—Zr cobalt based alloy commercially used as sputtering target in manufacture of data storage and electronic components in a crucible in a casting furnace under a vacuum of less than 10 microns and casting the melted alloy at a temperature of above 2800 degrees F. into a ceramic shell mold assembly preheated to above 2775 degrees F. and having three molds connected to a common pour cup by respective runners in a manner shown for mold 20 of FIG. 1. To make the melt in the crucible, cobalt charge material was charged first followed by tantalum charge material and then zirconium charge material so that the cobalt charge material could be melted slowly at the bottom of the crucible without an excessive superheat.

Each mold had a disc-shaped mold cavity of the type shown in FIG. 1 with a mold cavity diameter of 7.25 inch and thickness of 0.5 inch. Each target was solidified in the respective mold cavity as a multi-crystalline target by withdrawing the melt-filled shell mold assembly from the open bottom of the casting furnace at a withdrawal rate of 10-18 inches/hour. The targets were multi-crystalline rather than single crystal as a result of nucleation of additional crystals or grains above the pigtail crystal selector passage shown as 30 in FIG. 1. A single crystal target can be solidified by eliminating the nucleation of additional crystals or grains above the crystal selector passage. The shell molds were removed from the respective solidified sputtering target followed by removal of the gating connected to the solidified targets, leaving generally disc-shaped sputtering targets. Each solid disc-shaped solidified sputtering target had a <001> grain orientation aligned in the vertical direction in FIG. 1. A disc-shaped sputtering target made pursuant to this Example exhibited a pass through flux during subsequent sputtering that was an order of magnitude greater than that provided by a rolled sputtering target under similar sputtering conditions.

Similarly, a multicrystalline target microstructure, rather than a single crystal target microstructure, can be made by providing for grain nucleation directly from the chill plate without the use of the crystal selector of FIG. 1. That is, the grain nucleation chamber 32 communicates directly to the mold cavity 22.

### EXAMPLE 2

Columnar grain sputtering targets were made by melting a prealloyed Co—Pt—Cr—B cobalt based alloy commercially used as sputtering target in manufacture of flat screen displays and data storage components in a crucible in a casting furnace under a vacuum of less than 10 microns and casting the melted alloy at an alloy temperature of above 2450 degrees F. into a ceramic shell mold assembly preheated to above 2500 degrees F. and having four molds connected to a common pour cup by respective runners in a manner shown for mold 20′ of FIG. 2. Each mold had a plate-shaped (rectangular cross section) mold cavity of the type shown in FIG. 2 with mold cavity dimensions of 13.5 inch in height, 4.25 inches in width, and 0.5 inch in thickness. Each target was solidified in the respective mold cavity as a columnar grain target by withdrawing the melt-filled shell mold assembly from the open bottom of the casting furnace at a withdrawal rate of 6-10 inches/hour. The targets were columnar grain having a plurality of columnar shaped grains extending vertically through the mold cavity in FIG. 2. The shell molds were removed from the solidified sputtering targets followed by removal of the gating, leaving plate-shaped sputtering targets. The sputtering targets each had a <001> grain orientation aligned in the vertical direction in FIG. 2.

Although the invention has been described with respect to detailed embodiments thereof, it will be understood by those skilled in the art that various changes in form and detail thereof may be made without departing from the spirit and scope of the claimed invention.

We claim:

1. Method of making a sputtering target, including the steps of providing melted sputtering target material in a heated mold and solidifying the melted sputtering target material in the mold using a unidirectional heat removal process to produce a sputtering target having a controlled grain orientation.

2. The method of claim 1 wherein the melted material is solidified to produce a multi-crystalline sputtering target.

3. The method of claim 1 wherein the melted material is solidified to produce a columnar grain target having a plurality of elongated grains extending along an axis of the target.

4. The method of claim 1 wherein the melted material is solidified to produce a single crystal sputtering target.

5. The method of claim 1 wherein the melted material is solidified in a heated ceramic investment shell mold.

6. The method of claim 1 wherein the melted material is solidified in a heated metallic mold.

7. The method of claim 1 wherein the target is a cobalt alloy.

8. The method of claim 7 wherein the cobalt alloy includes an alloying element selected from the group consisting of boron, chromium, platinum, tantalum, ruthenium, rhenium, niobium, copper, vanadium, silicon, silver, gold, iron, aluminum, and nickel.

9. The method of claim 1 wherein the target is an iron alloy.

10. The method of claim 9 wherein the iron alloy includes an alloying element selected from the group consisting of boron, chromium, platinum, tantalum, ruthenium, rhenium, niobium, copper, vanadium, silicon, silver, gold, aluminum, zirconium and cobalt.

11. The method of claim 1 wherein the target is a nickel alloy.

12. The method of claim 11 wherein the nickel alloy includes an alloying element selected from the group consisting of boron, chromium, platinum, tantalum, ruthenium, rhenium, niobium, copper, vanadium, silicon, silver, gold, iron, aluminum, and cobalt.

13. The method of claim 1 wherein the target is a chromium alloy.

14. The method of claim 13 wherein the chromium alloy includes an alloying element selected from the group consisting of boron, cobalt, platinum, tantalum, ruthenium, rhenium, niobium, copper, vanadium, silicon, silver, gold, iron, aluminum, and nickel.

15. The method of claim 1 wherein the target is a tantalum alloy.

16. The method of claim 15 wherein the tantalum alloy includes an alloying element selected from the group consisting of boron, cobalt, platinum, iron, ruthenium, rhenium, niobium, copper, vanadium, silicon, silver, gold, chromium, aluminum, and nickel.

17. A cobalt alloy sputtering target having a controlled selectively oriented multicrystalline microstructure or a selectively oriented single crystal microstructure.

18. The target of claim 17 having a shape of a solid or annular disc.

19. The target of claim 17 having a shape of a cylindrical billet.

20. The target of claim 17 having a shape with a rectangular cross-section.

21. A iron alloy sputtering target having a controlled selectively oriented multicrystalline microstructure or a selectively oriented single crystal microstructure.

22. The target of claim 21 having a shape of a solid or annular disc.

23. The target of claim 21 having a shape of a cylindrical billet.

24. The target of claim 21 having a shape with a rectangular cross-section.

25. A nickel alloy sputtering target having a controlled selectively oriented multicrystalline microstructure or a selectively oriented single crystal microstructure.

26. The target of claim 25 having a shape of a solid or annular disc.

27. The target of claim 25 having a shape of a cylindrical billet.

28. The target of claim 25 having a shape with a rectangular cross-section.

29. A chromium alloy sputtering target having a controlled selectively oriented multicrystalline microstructure or a selectively oriented single crystal microstructure.

30. The target of claim 29 having a shape of a solid or annular disc.

31. The target of claim 29 having a shape of a cylindrical billet.

32. The target of claim 29 having a shape with a rectangular cross-section.

33. A tantalum alloy sputtering target having a controlled selectively oriented multicrystalline microstructure or a selectively oriented single crystal microstructure.

34. The target of claim 33 having a shape of a solid or annular disc.

35. The target of claim 33 having a shape of a cylindrical billet.

36. The target of claim 33 having a shape with a rectangular cross-section.
